(19) United States
(12) Patent Application Publication
(10) Pub. No.: US 2013/0275837 A1
(43) Pub. Date: Oct. 17, 2013

(54) PACKET FORWARD ERROR CORRECTION

(71) Applicant: REAL TIME LOGIC, INC., San Diego, CA (US)

(72) Inventors: Douglas James Heath, Aurora, CO (US); Martin Andrew Polloconi, Parker, CO (US)

(73) Assignee: REAL TIME LOGIC, INC., San Diego, CA (US)

(21) Appl. No.: 13/649,021

(22) Filed: Oct. 10, 2012

Related U.S. Application Data
(60) Provisional application No. 61/623,978, filed on Apr. 13, 2012.

(51) Int. Cl. H03M 13/05; G06F 11/10

(52) U.S. Cl. 714/776; 714/E11.053

(57) ABSTRACT

Performing packet forward error correction on received data, including: receiving packets including parity packets from a data stream; reading identifier information in a packet header to determine if there were at least one dropped packet in the data stream; processing remaining packets of the received packets when it is determined that there were at least one dropped packet, wherein the remaining packets including the parity packets are processed to recover the at least one dropped packet; and inserting the at least one recovered packet back into another data stream.

### BACKGROUND

1. Field of the Invention

The present invention relates to a packet-switched communication network, and more specifically, to packet forward error correction used in the packet-switched communication network.

2. Background

In a packet-switched network, a message to be sent is divided into blocks, or data packets, of fixed or variable length. The packets are then sent individually over the network through multiple locations and then reassembled at a final location before being delivered to a user at a receiving end. To ensure proper transmission and re-assembly of the blocks of data at the receiving end, various control data, such as sequence and verification information, is typically appended to each packet in the form of a packet header. At the receiving end, the packets are then reassembled and transmitted to an end user in a format compatible with the user's equipment.

A variety of packet switching protocols are available, and these protocols range in degree of efficiency and reliability. For example, Transmission Control Protocol (TCP) is a reliable connection-oriented protocol, which includes intelligence necessary to confirm successful transmission between sending and receiving ends in the network. According to TCP, each packet is marked in its header with a sequence number to allow the receiving end to properly reassemble the packets into the original message. The receiving end is then typically configured to acknowledge receipt of packets and expressly request the sending end to retransmit any lost packets. However, TCP introduces delay into packet transmission, due to its need to request retransmission of these lost packets. While this delay may not be a significant problem in the transmission of pure data signals (such as an e-mail message), the delay can unacceptably disrupt the transmission of real-time media signals (such as digitized voice, video or audio). User Datagram Protocol (UDP), in contrast, is an unreliable connectionless protocol, which facilitates sending and receiving of packets but does not include any intelligence to establish that a packet successfully reached its destination. Therefore, a need exists for an improved system of responding to and correcting packet loss errors.

### SUMMARY

The present invention provides for packet forward error correction.

In one implementation, a method of performing packet forward error correction on received data is disclosed. The method includes: receiving packets including parity packets from a data stream; reading identifier information in a packet header to determine if there were at least one dropped packet in the data stream; processing remaining packets of the received packets when it is determined that there were at least one dropped packet, wherein the remaining packets including the parity packets are processed to recover the at least one dropped packet; and inserting the at least one recovered packet back into another data stream.

In another implementation, a method of transmitting data using packet forward error correction is disclosed. The method includes: receiving packets as source data from an application; arranging each packet according to user-defined parameters into groups; calculating a parity packet for each group of the groups; placing the calculated parity packet for each group between each set of packets to form output packets; and releasing the output packets into a data stream.

In yet another implementation, a packet forward error correction (PFEC) receiver is disclosed. The PFEC receiver includes: an interface configured to receive packets including parity packets from a data stream, and read identifier information in a packet header to determine if there were at least one dropped packet in the data stream; and a processor configured to process remaining packets of the received packets when it is determined that there were at least one dropped packet.

In a further implementation, a packet forward error correction (PFEC) transmitter is disclosed. The PFEC transmitter includes: an interface configured to receive packets as source data from an application; and a processor configured to arrange the received packets according to user-defined parameters into groups, calculate a parity packet for each group of the groups, place the calculated parity packet for each group between each set of packets to form output packets, and release the output packets into a data stream.

Other features and advantages of the present invention will become more readily apparent to those of ordinary skill in the art after reviewing the following detailed description and accompanying drawings.

### BRIEF DESCRIPTION OF THE DRAWINGS

FIG. 1 is a functional block diagram of a packet forward error correction transmitter configured in accordance with one implementation of the present invention.

FIG. 2 is a functional block diagram of a packet forward error correction receiver configured in accordance with one implementation of the present invention.

FIG. 3A is a flow diagram illustrating a transmission process for packet forward error correction in accordance with one implementation of the present invention.

FIG. 3B is a flow diagram illustrating a reception process for packet forward error correction in accordance with one implementation of the present invention.

FIG. 4A illustrates a representation of a computer system and a user.

FIG. 4B is a functional block diagram illustrating the computer system hosting the packet forward error correction (PFEC) transceiver.

### DETAILED DESCRIPTION

As discussed above, the TCP protocol offers one method for responding to loss of packets in a digital transmission network. According to TCP, the receiving node may be configured to acknowledge receipt of packets and expressly request the transmitting node to retransmit any lost packets. This request and retransmission system is generally accurate. However, as noted above, the system is not well suited for use in the context of real-time media transmissions, because the transmission of such signals is very sensitive to the delay introduced by retransmission requests.

Rather than employing a request and retransmission system, greater efficiency in packet loss correction may be achieved by transmitting a correction code of some sort concurrently with the payload data, thereby providing the receiving end with sufficient information to recover lost packets. Several error correction code mechanisms are available for this purpose.

Certain implementations as described herein provide for packet forward error correction which is tailored to individual links to ensure reliable delivery and minimum overhead. After reading this description it will become apparent how to implement the invention in various implementations and applications. Although various implementations of the present invention will be described herein, it is understood that these implementations are presented by way of example only, and not limitation. As such, this detailed description of various implementations should not be construed to limit the scope or breadth of the present invention.

In one implementation, the packet forward error correction includes a pair of configurations: one on the transmit side and another on the receive side of the connection. However, the number of components on each side (i.e., the transmit side or receive side) can be scaled to meet the needs of each application.

On the transmit side, the packet forward error correction transmitter receives packets as source data from an application with packet identification information included in the packet header. The packet identification information can include the packet order, whether the packet is a parity packet, and other related information such as the packet size, in the packet header. In this implementation, the packet forward error correction transmitter arranges each packet according to the user-defined parameters such as group and size. The transmitter calculates the parity packet for each group and releases the packets (including the parity packet) once the parity calculation is done. The release of the packets can be done in real-time. The packet forward error correction transmitter then places the calculated parity packet for each group of packets and releases the packets into the network stream.

On the receive side, the packet forward error correction receiver receives packets from the network stream with the same size and group parameters as the transmit side. Upon receipt of the packets, the packet forward error correction receiver reads the identifier information in the packet header to determine if there was any packet drop in the stream. If a packet drop is detected, the packet forward error correction receiver processes the remaining packets and the parity packet to recover the dropped packet and insert the recovered packet back into the data stream. The receiver holds the packets until each set of packets is received, and then releases the packets to an application in the original order as transmitted without the parity packets.

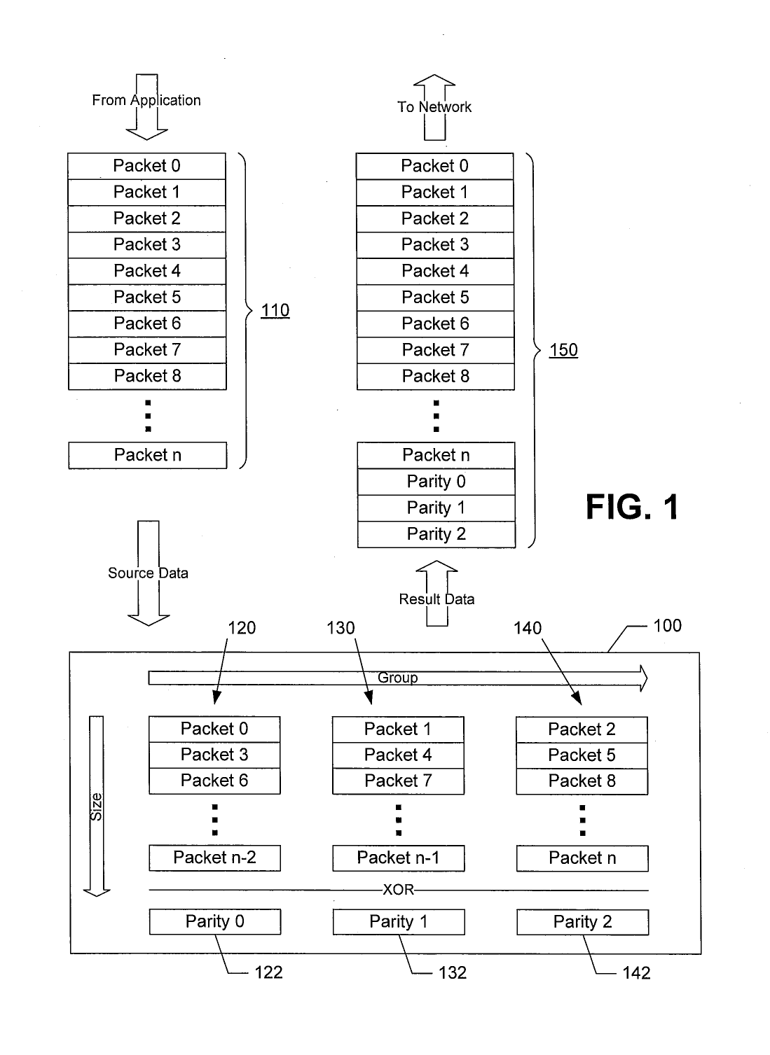

FIG. 1 is a functional block diagram of a packet forward error correction transmitter 100 configured in accordance with one implementation of the present invention. The transmitter 100 is configured to receive n packets 110 as source data from an application with packet identification information included in the packet header. As described above, the packet identification information can include the packet order, whether the packet is a parity packet, and other related information such as the packet size. The packet forward error correction transmitter 100 arranges each packet according to the user-defined parameters such as number of groups per set and group size (number of packets per group). In the illustrated implementation of FIG. 1, the packets are arranged into three groups, each group having a size of (n/3) packets. For example, the first group 120 includes Packet 0, Packet 3, Packet 6, . . . , and Packet n−2. The second group 130 includes Packet 1, Packet 4, Packet 7, . . . , and Packet n−1. The third group 140 includes Packet 2, Packet 5, Packet 8, . . . , and Packet n.

The transmitter 100 calculates the parity value for each group 120, 130, 140 by computing the XOR value of the packets within that group. For example, the parity value 122 (i.e., Parity 0) for the first group 120 is calculated by computing the XOR value of Packet 0, Packet 3, Packet 6, . . . , Packet n−2. The parity value 132 (i.e., Parity 1) for the second group 130 is calculated by computing the XOR value of Packet 1, Packet 4, Packet 7, . . . , and Packet n−1. The parity value 142 (i.e., Parity 2) for the third group 140 is calculated by computing the XOR value of Packet 2, Packet 5, Packet 8, . . . , and Packet n. It should be noted that although the illustrated implementation arranges the packets into three groups and calculates one parity value for each group, the packets can be arranged into any number of groups and any number of parity values can be calculated for each group. Further, the transmitter 100 then places the calculated parity packets 122, 132, 142 for each group between each set of packets and releases the packets 150 into the network stream.

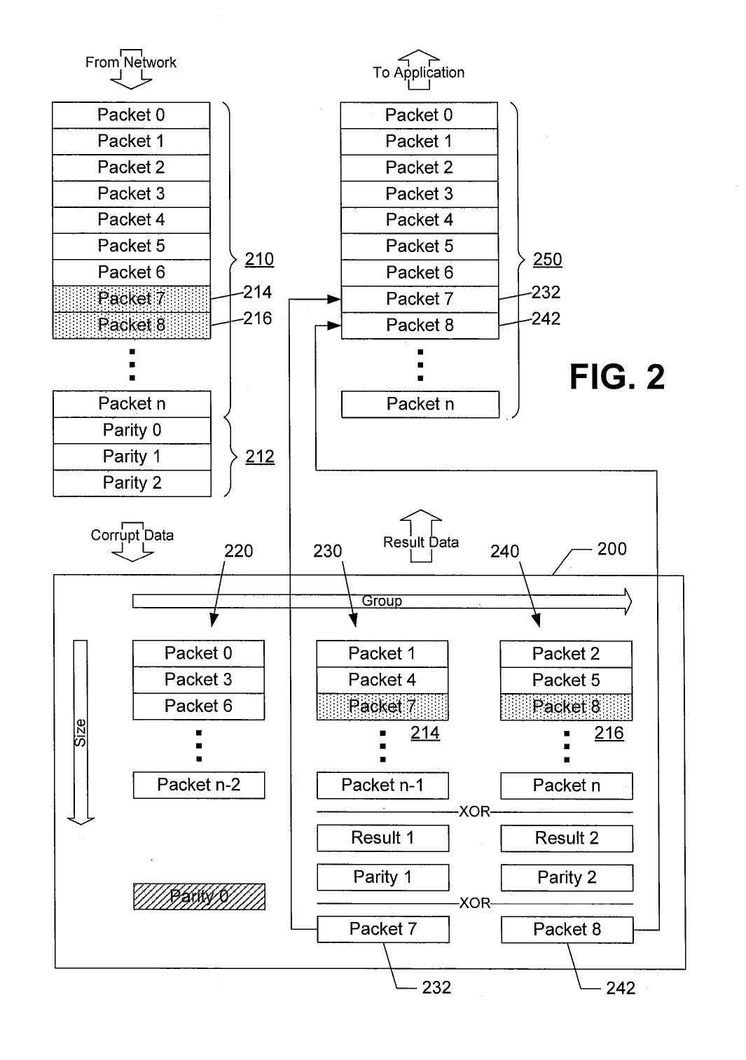

FIG. 2 is a functional block diagram of a packet forward error correction receiver 200 configured in accordance with one implementation of the present invention. Upon receipt of the packets 210 including the parity packets 212 from the network stream with the same size and group parameters as the transmit side, the packet forward error correction receiver 200 reads the identifier information in the packet header to determine if there was any packet drop in the stream. If a packet drop is detected, the packet forward error correction receiver 200 processes the remaining packets 210 and the parity packet 212 to recover the dropped packet and insert the recovered packet back into the data stream.

In the illustrated implementation of FIG. 2, the receiver 200 detects that two packets are dropped, and arranges the received packets 210 and the parity packets 212 into three groups 220, 230, 240. The receiver 200 also detects that dropped Packet 7 (214) belongs to the second group 230 while dropped Packet 8 (216) belongs to the third group 240. Thus, the receiver 200 determines that Parity 0, which is a parity packet for the first group 220, can be ignored.

To recover dropped Packet 7 (214), which was in the second group of packets 230, the receiver 200 computes the XOR value of the remaining packets of the second group 230 (i.e., Packet 1, Packet 4, . . . , and Packet n−1). The XOR value is shown as Result 1 in FIG. 2. The receiver 200 then computes the XOR value of Result 1 and the parity packet (Parity 1) for the second group 230 to form recovered Packet 7 (232).

To recover dropped Packet 8 (216), which was in the third group of packets 240, the receiver 200 computes the XOR value of the remaining packets of the third group 240 (i.e., Packet 2, Packet 5, . . . , and Packet n). The XOR value is shown as Result 2 in FIG. 2. The receiver 200 then computes the XOR value of Result 2 and the parity packet (Parity 2) for the third group 240 to form recovered Packet 8 (242).

The receiver 200 then inserts the recovered packet 232, 242 back into the data stream. The receiver 200 holds the packets 250 until each set of packets is received, and then releases the packets 250 to an application in the original order as transmitted without the parity packets.

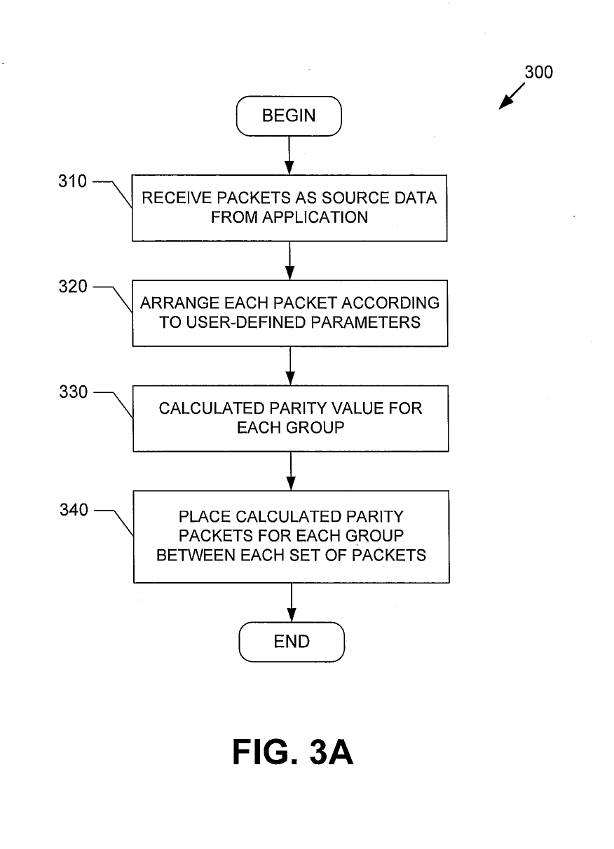

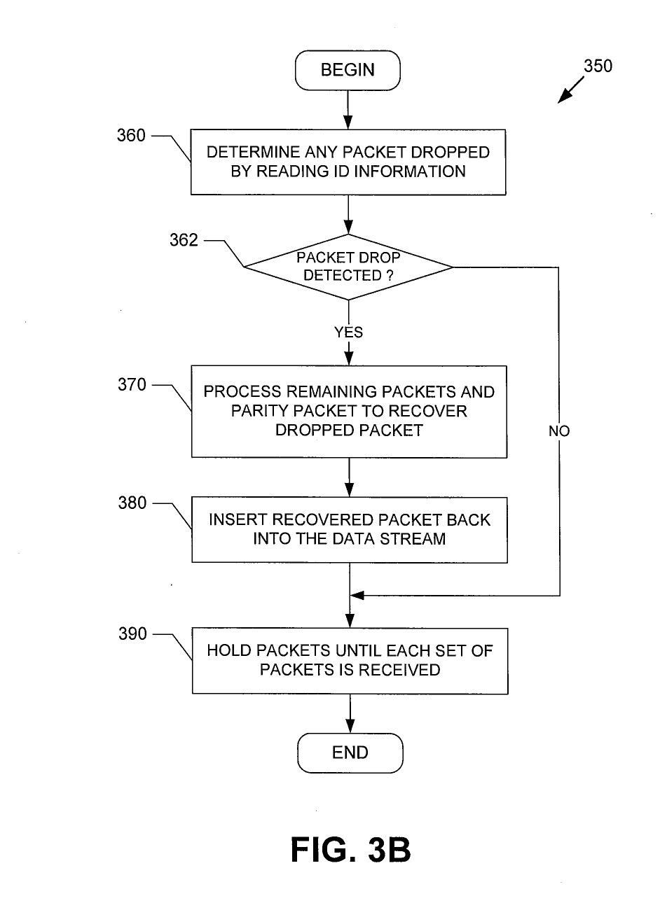

FIG. 3A is a flow diagram illustrating a transmission process 300 for packet forward error correction in accordance with one implementation of the present invention. Initially, packets are received as source data from an application, at box 310, with packet identification information included in the packet header. As described above, the packet identification information can include the packet order, whether the packet is a parity packet, and other related information such as the packet size. Each packet is arranged, at box 320, according to the user-defined parameters such as group and size. In one implementation, the packets are arranged into three groups, each group having a size of (n/3) packets. For example, the first group 120 includes Packet 0, Packet 3, Packet 6, . . . , and Packet n−2. The second group 130 includes Packet 1, Packet 4, Packet 7, . . . , and Packet n−1. The third group 140 includes Packet 2, Packet 5, Packet 8, . . . , and Packet n.

The parity value for each group is calculated, at box 330, by computing, for example, the XOR value of the packets within that group. The calculated parity packets for each group are then placed, at box 340, between each set of packets, which are released into the network stream.

FIG. 3B is a flow diagram illustrating a reception process 350 for packet forward error correction in accordance with one implementation of the present invention. Upon receipt of the packets including the parity packets from the network stream with the same size and group parameters as the transmit side, the identifier information in the packet header is read, at box 360, to determine if there was any packet drop in the stream. If a packet drop is detected, at box 362, the remaining packets and the parity packet is processed, at box 370, to recover the dropped packet and insert the recovered packet back into the data stream. For example, if it is detected that a packet is dropped from a group, the XOR value (i.e., the resultant value) of the remaining packets of that group is first computed. The dropped packet is then recovered by computing the XOR value of the resultant value and the parity packet of that group. The recovered packet is inserted back into the data stream, at box 380. The packets are held, at box 390, until each set of packets is received, and then releases the packets to an application in the original order as transmitted without the parity packets.

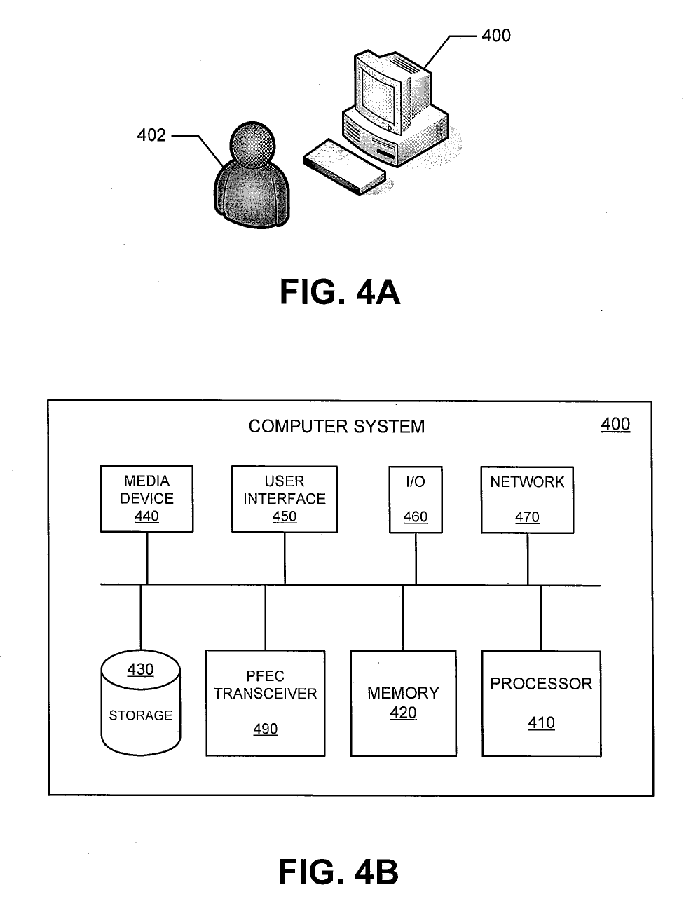

FIG. 4A illustrates a representation of a computer system 400 and a user 402. In one implementation, the user 402 uses the computer system 400 to perform either transmission or reception process of packet forward error correction. In one implementation, the computer system 400 is configured as a packet forward error correction transmitter 100. In another implementation, the computer system 400 is configured as a packet forward error correction receiver 200.

FIG. 4B is a functional block diagram illustrating the computer system 400 hosting the packet forward error correction (PFEC) transceiver 490. The controller 410 is a programmable processor and controls the operation of the computer system 400 and its components. The controller 410 loads instructions (e.g., in the form of a computer program) from the memory 420 or an embedded controller memory (not shown) and executes these instructions to control the system.

Memory 420 stores data temporarily for use by the other components of the computer system 400. In one implementation, memory 420 is implemented as RAM. In another implementation, memory 420 also includes long-term or permanent memory, such as flash memory and/or ROM.

Storage 430 stores data temporarily or long term for use by other components of the computer system 400, such as for storing data and program of the PFEC transceiver 490. Storage 430 is sometimes referred to as a computer-readable storage medium which stores non-transitory data. In one implementation, storage 430 is a hard disk drive.

In its execution, the PFEC transceiver 490 is loaded into the memory 420 or storage 430 as a software system. Alternatively, this service can be implemented as separate hardware components in the computer system 400.

The media device 440 receives removable media and reads and/or writes data to the inserted media. In one implementation, for example, the media device 440 is an optical disc drive.

The user interface 450 includes components for accepting user input from the user of the computer system 400 and presenting information to the user. In one implementation, the user interface 450 includes a keyboard, a mouse, audio speakers, and a display. The controller 410 uses input from the user to adjust the operation of the computer system 400.

The I/O interface 460 includes one or more I/O ports to connect to corresponding I/O devices, such as external storage or supplemental devices (e.g., a printer or a PDA). In one implementation, the ports of the I/O interface 460 include ports such as: USB ports, PCMCIA ports, serial is ports, and/or parallel ports. In another implementation, the I/O interface 460 includes a wireless interface for communication with external devices wirelessly.

The network interface 470 includes a wired and/or wireless network connection, such as an RJ-45 or “Wi-Fi” interface (including, but not limited to 302.11) supporting an Ethernet connection.

The computer system 400 includes additional hardware and software typical of computer systems (e.g., power, cooling, operating system), though these components are not specifically shown in FIG. 4B for simplicity. In other implementations, different configurations of the computer system can be used (e.g., different bus or storage configurations or a multi-processor configuration).

The above description of the disclosed implementations is provided to enable any person skilled in the art to make or use the invention. Various modifications to these implementations will be readily apparent to those skilled in the art, and the generic principles described herein can be applied to other implementations without departing from the spirit or scope of the invention. Accordingly, additional implementations and variations are also within the scope of the invention. For example, although the implementations discussed above focus on using packets of data and parity, other groupings of data such as blocks (e.g., pixel blocks) can be used to recover dropped data. Further, it is to be understood that the description and drawings presented herein are representative of the subject matter which is broadly contemplated by the present invention. It is further understood that the scope of the present invention fully encompasses other implementations that may become obvious to those skilled in the art and that the scope of the present invention is accordingly limited by nothing other than the appended claims.

1. A method of performing packet forward error correction on received data, the method comprising:
receiving packets including parity packets from a data stream;
reading identifier information in a packet header to determine if there were at least one dropped packet in the data stream;
processing remaining packets of the received packets when it is determined that there were at least one dropped packet,
wherein the remaining packets including the parity packets are processed to recover the at least one dropped packet; and
inserting the at least one recovered packet back into another data stream.

2. The method of claim 1, wherein said another data stream is a data stream for an application.

3. The method of claim 2, further comprising:
holding total packets until each set of packets is received,
wherein the total packets comprises the remaining packets and the at least one recovered packet; and
releasing the total packets to the application in an original order as transmitted without the parity packets.

4. The method of claim 1, wherein processing remaining packets of the received packets comprises
arranging the remaining packets into a same number of groups as on the transmitting side; and
identifying a particular group number of the at least one dropped packet.

5. The method of claim 4, further comprising
computing an XOR value of the remaining packets in the particular group number to generate a resultant packet.

6. The method of claim 5, further comprising
computing an XOR value of the result packet and a parity packet for the particular group number to generate the at least one recovered packet.

7. A method of transmitting data using packet forward error correction, the method comprising:
receiving packets as source data from an application;
arranging each packet according to user-defined parameters into groups;
calculating a parity packet for each group of the groups;
placing the calculated parity packet for each group between each set of packets to form output packets; and
releasing the output packets into a data stream.

8. The method of claim 7, wherein the received packets include
packet identification information in a packet header.

9. The method of claim 8, wherein the packet identification information includes
a packet order, whether a packet is a parity packet, and other related information including a packet size.

10. The method of claim 7, wherein the data stream is a network stream.

11. The method of claim 7, wherein calculating a parity packet for each group comprises
computing an XOR value of the received packets for said each group.

12. A packet forward error correction (PFEC) receiver, comprising:
an interface configured to receive packets including parity packets from a data stream, and read identifier information in a packet header to determine if there were at least one dropped packet in the data stream; and
a processor configured to process remaining packets of the received packets when it is determined that there were at least one dropped packet.

13. The PFEC receiver of claim 12, wherein the processor processes the remaining packets to recover the at least one dropped packet.

14. The PFEC receiver of claim 13, wherein the processor further comprises
an output module configured to insert at least one recovered packet back into another data stream.

15. The PFEC receiver of claim 14, wherein said another data stream is a data stream for an application.

16. The PFEC receiver of claim 12, wherein the processor further comprises:
an arranging unit configured to arrange the remaining packets into a same number of groups as on the transmitting side; and
identifying a particular group number of the at least one dropped packet.

17. The PFEC receiver of claim 16, wherein the processor further comprises:
a first XOR unit configured to compute an XOR value of the remaining packets within the particular group number to produce a resultant packet; and
a second XOR unit configured to compute an XOR value of the resultant packet and a parity packet of the particular group number to recover the at least one dropped packet.

18. A packet forward error correction (PFEC) transmitter, comprising:
an interface configured to receive packets as source data from an application; and
a processor configured to arrange the received packets according to user-defined parameters into groups, calculate a parity packet for each group of the groups, place the calculated parity packet for each group between each set of packets to form output packets, and release the output packets into a data stream.

19. The PFEC transmitter of claim 18, wherein the data stream is a network stream.
